(19) United States
(12) Patent Application Publication
(10) Pub. No.: US 2026/0165135 A1
(43) Pub. Date: Jun. 11, 2026

(54) SEMICONDUCTOR DEVICE AND METHOD OF MANUFACTURING THE SAME

(71) Applicant: Renesas Electronics Corporation, Tokyo (JP)

(72) Inventor: Yasuhiko KITAMURA, Tokyo (JP)

(21) Appl. No.: 19/367,066

(22) Filed: Oct. 23, 2025

(30) Foreign Application Priority Data
Dec. 11, 2024 (JP) 2024-216996

(51) Int. Cl. H01L 23/00; H01L 23/532; H10D 30/65; H10D 64/00

(52) U.S. Cl. CPC H10W 42/00; H10D 30/65; H10D 64/112; H10W 20/47

(57) ABSTRACT

An interlayer insulating film is formed on an upper surface of a semiconductor substrate. A plurality of wirings is formed on the interlayer insulating film. The interlayer insulating film has a BPSG film and a PSG film formed on the BPSG film. A gettering layer containing phosphorus is formed in the PSG film. A concentration of phosphorus in the gettering layer is higher than a concentration of phosphorus in the PSG film.

### CROSS-REFERENCE TO RELATED APPLICATIONS

The disclosure of Japanese Patent Application No. 2024-216996 filed on Dec. 11, 2024 having the specification, drawings and abstract is incorporated herein by reference in its entirety.

### BACKGROUND

The present invention relates to a semiconductor device and a method of manufacturing the semiconductor device.

Semiconductor devices comprising semiconductor elements such as power MOSFETs (Metal Oxide Semiconductor Field Effect Transistors) or IGBTs (Insulated Gate Bipolar Transistors) have been widely used. Such a semiconductor device capable of withstanding a high voltage includes a cell region in which a plurality of semiconductor elements is formed and an outer peripheral region surrounding the cell region in plan view. The outer peripheral region is utilized as a termination region to enhance a breakdown voltage of the semiconductor device.

There are disclosed techniques listed below.

[Patent Document 1] Japanese Unexamined Patent Application Publication No. 2019-192678

For example, Patent Document 1 discloses that a guard ring wiring is formed in the outer peripheral region. In addition, a plurality of field plate wirings and a plurality of field-limiting rings (plurality of p-type impurity regions) are formed between the plurality of semiconductor elements and the guard ring wiring. The plurality of field plate wirings and the plurality of field-limiting rings allow a depletion layer to extend in a direction from the plurality of semiconductor elements to the guard ring wires. This mitigates a high electric field associated with the high voltage applied to the plurality of semiconductor elements.

In addition, a source wiring connected to a source electrode and a gate wiring connected to a gate pad are formed between the plurality of semiconductor elements and the plurality of field plate wirings. The source wiring, the gate wiring, the plurality of field plate wirings, and the guard ring wiring are each formed on the interlayer insulating film.

After a semiconductor device is packaged, a breakdown test may be performed as a reliability test for the semiconductor device. In the breakdown test, for example, 0 V is applied to each of the gate electrode and source electrode, a high voltage of 1,000 V or more is applied to the drain electrode, and a breakdown state is maintained for an extended period of time. At this time, variation in the breakdown voltage from an initial breakdown voltage of the semiconductor device is measured.

In a breakdown test, a depletion layer is first formed around the field-limiting ring closest to the plurality of semiconductor elements and extends in a direction toward the guard ring wiring. Before avalanche breakdown occurs, the depletion layer reaches the field-limiting ring that is second-closest to the plurality of semiconductor elements. In this manner, an electric field is gradually mitigated by the plurality of field-limiting rings such that the electric field generated in the outer peripheral region can be mitigated. In addition, since the plurality of field plate wirings can increase the spacing between equipotential lines, the electric field can be further mitigated.

Here, depending on a configuration of the interlayer insulating film, problems may arise in which an extension of the depletion layer extending from the plurality of field-limiting rings becomes smaller, making the breakdown voltage of the semiconductor device in the outer peripheral region to significantly vary. In other words, a problem leading to a decrease in reliability of the semiconductor device arises.

Other problems and novel features will become clear from the description of the present specification and accompanying drawings.

### SUMMARY

A semiconductor device according to one embodiment comprises an interlayer insulating film formed on the upper surface of the semiconductor substrate, and a plurality of wirings formed on the interlayer insulating film. The interlayer insulating film has a BPSG film and a PSG film formed on the BPSG film. A gettering layer containing phosphorus is formed in the PSG film. A concentration of phosphorus in the gettering layer is higher than a concentration of phosphorus in the PSG film.

A method of manufacturing a semiconductor device according to one embodiment comprises steps of (a) preparing a semiconductor substrate of a first conductivity type, the semiconductor substrate having an upper surface, (b) forming the BPSG film on the upper surface of the semiconductor substrate, (c) forming the PSG film on the BPSG film, (d) forming a gettering layer in the PSG film by injecting phosphorus into the PSG film with an ion implantation, and (e) after the step of (d), forming a plurality of wirings on the PSG film. A concentration of phosphorus in the gettering layer is higher than a concentration of phosphorus in the PSG film.

According to one embodiment, reliability of the semiconductor device can be improved.

### BRIEF DESCRIPTION OF THE DRAWINGS

FIG. 1 is a plan view of a semiconductor device according to a first embodiment.

FIG. 2 is a cross-sectional view of an outer peripheral region and a cell region of the first embodiment.

FIG. 3 is a cross-sectional view of a portion of the outer peripheral region and the cell region of the first embodiment.

FIG. 4 is a cross-sectional view of positive mobile ions in the outer peripheral region trapped in the interlayer insulating film.

FIG. 5 is a graph showing test results by the present inventors.

FIG. 6 is a cross-sectional view of the semiconductor device of the first embodiment in a manufacturing step thereof.

FIG. 7 is a cross-sectional view of the semiconductor device in a manufacturing step continued from FIG. 6.

FIG. 8 is a cross-sectional view of the semiconductor device in a manufacturing step continued from FIG. 7.

FIG. 9 is a cross-sectional view of the semiconductor device in a manufacturing step continued from FIG. 8.

FIG. 10 is a cross-sectional view of the semiconductor device in a manufacturing step continued from FIG. 9.

FIG. 11 is a cross-sectional view of the semiconductor device in a manufacturing step continued from FIG. 10.

FIG. 12 is a cross-sectional view of the semiconductor device in a manufacturing step continued from FIG. 11.

FIG. 13 is a cross-sectional view of the semiconductor device in a manufacturing step continued from FIG. 12.

FIG. 14 is a cross-sectional view of a portion of the outer peripheral region and the cell region of a second embodiment.

FIG. 15 is a cross-sectional view of a portion of the outer peripheral region and the cell region of a third embodiment.

### DETAILED DESCRIPTION

Hereinafter, embodiments of the present invention will be described in detail with reference to the drawings. In all drawings used to explain the embodiments, the same reference sign is used for members having identical functions, and redundant descriptions thereof are omitted. In addition, in the following embodiments, descriptions of the same or similar parts are not repeated unless specifically necessary.

In addition, X, Y and Z directions described in the present application mutually intersect one another and are mutually orthogonal to one another. In the present application, the Z direction is a vertical direction, a depth direction, or a thickness direction of a structure. In addition, expressions such as “plan view” used in this application refer to a “plane” formed by the X and Y directions, and indicate a view of this “plane” from the Z direction.

### First Embodiment

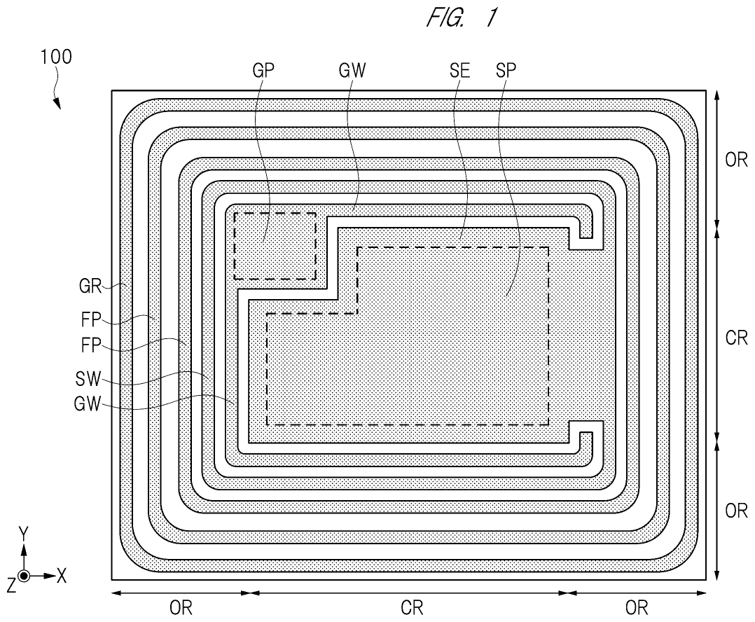

Hereinafter, a semiconductor device 100 according to a first embodiment will be described with reference to FIGS. 1 to 3.

As shown in FIG. 1, the semiconductor device 100 comprises a cell region CR in which a plurality of semiconductor elements is formed, and an outer peripheral region OR surrounding the cell region CR in plan view. In the first embodiment, n-type MOSFETs 1Q are shown as an example of the semiconductor elements.

As shown in FIG. 1, the semiconductor device 100 comprises a plurality of wirings. A source electrode SE is formed as a wiring in the cell region CR. A plurality of MOSFETs 1Q is formed below the source electrode SE. A gate wiring GW, a source wiring SW, a plurality of field plate wirings FP, and a guard ring wiring GR are each formed as a wiring in the outer peripheral region OR.

The gate wiring GW surrounds the source electrode SE in plan view. The source wiring SW is connected to the source electrode SE and is formed so as to surround the gate wiring GW in plan view. The plurality of field plate wirings FP is formed so as to surround the source wiring SW in plan view. The guard ring wiring GR is formed so as to surround the plurality of field plate wirings FP in plan view.

Note that, although the first embodiment shows an example where two field plate wirings FP are provided, the number of field plate wirings FP can be changed as necessary and may be three or more.

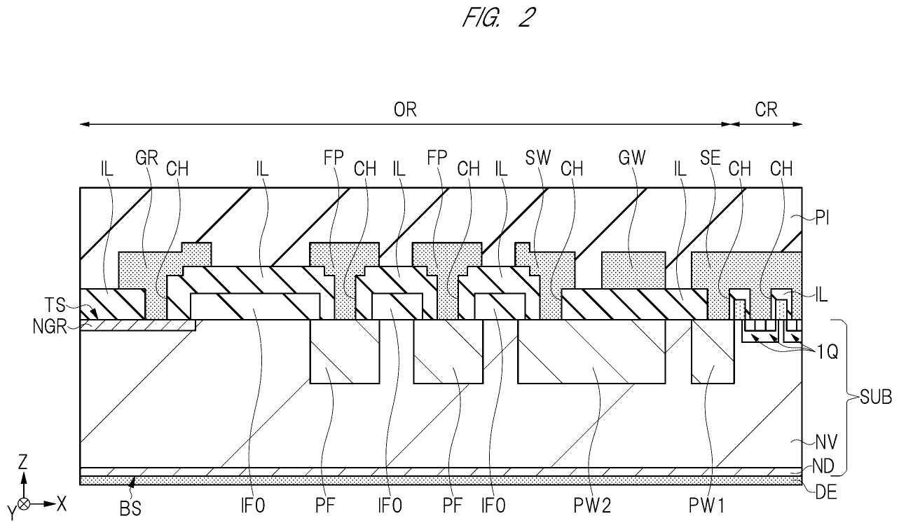

In addition, as shown in FIG. 2, the source electrode SE, the gate wiring GW, the source wiring SW, the plurality of field plate wirings FP, and the guard ring wiring GR are covered by a protective film PI. An opening is formed in a portion of the protective film PI. The protective film PI is a resin film such as a polyimide film.

As shown by the dashed lines in FIG. 1, a source pad SP is a portion of the source electrode SE that is exposed at the opening of the protective film PI. A gate pad GP is a portion of the gate wiring GW that is exposed at the opening of the protective film PI. External connection members are connected to the source pad SP and the gate pad GP such that the semiconductor device 100 can be electrically connected to another semiconductor device, a lead frame, or a wiring substrate. Note that the external connection member may be a wire made of aluminum, gold, or copper, or a clip made of a copper plate.

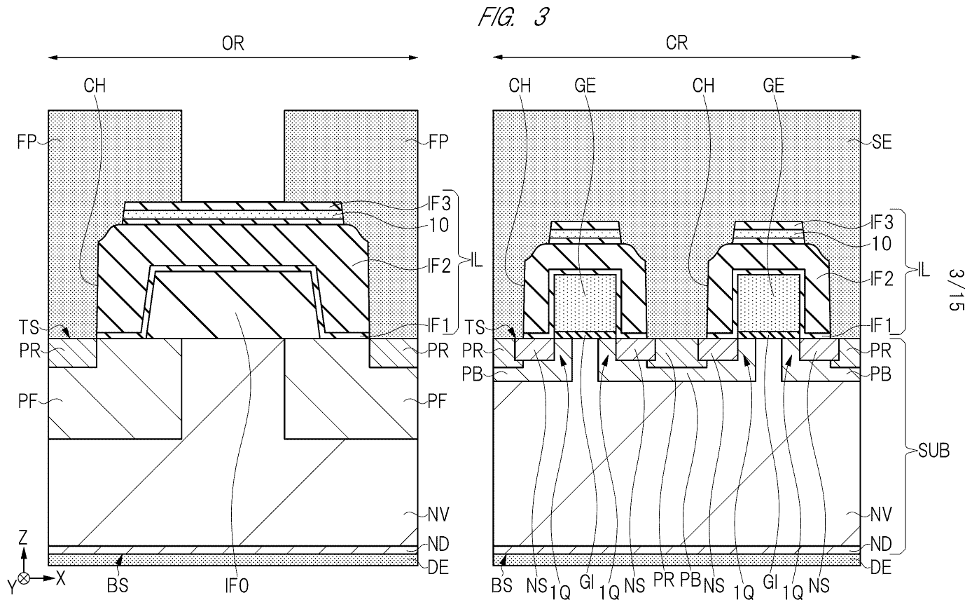

Hereinafter, a cross-sectional structure of the outer peripheral region OR and a cross-sectional structure of the MOSFETs 1Q formed in the cell region CR will be described with reference to FIGS. 2 and 3. Note that the outer peripheral region OR of FIG. 3 is a portion of FIG. 2, with the structure surrounding the plurality of field plate wirings FP enlarged. In addition, the protective film PI shown in FIG. 2 is omitted in FIG. 3.

### Structure of Mosfets in Cell Region

First, the structure of the MOSFETs 1Q in the cell region CR will be described. As shown in FIG. 3, a semiconductor substrate SUB has an upper surface TS and a lower surface BS, and is made of n-type silicon. The semiconductor substrate SUB has an n-type drift region NV and an n-type drain region ND. The drain region ND is formed in the semiconductor substrate SUB so as to have a predetermined thickness in a direction from the lower surface BS of the semiconductor substrate SUB toward the upper surface TS of the semiconductor substrate SUB. The drift region NV is formed in the semiconductor substrate SUB and is located on the drain region ND. An impurity concentration in the drain region ND is higher than an impurity concentration in the drift region NV.

The semiconductor substrate may be an n-type monocrystalline silicon substrate, or may be a stack including an n-type silicon substrate and an n-type semiconductor layer formed on the n-type silicon substrate.

A drain electrode DE is formed on the lower surface BS of the semiconductor substrate SUB. The drain electrode DE is made of a single layer of metal film such as an aluminum film, a titanium film, a nickel film, a gold film, or a silver film, or is made of a multilayer film in which these metal films are suitably stacked. The drain region ND and the drain electrode DE are formed over the entire lower surface BS of the semiconductor substrate SUB. A drain potential is supplied from the drain electrode DE to the semiconductor substrate SUB (drain region ND, drift region NV).

A gate electrode GE is formed on the upper surface TS of the semiconductor substrate SUB via a gate insulating film GI. The gate insulating film GI is made of, for example, a silicon oxide film. The gate electrode GE is made of, for example, a polycrystalline silicon film in which n-type impurities are introduced.

A p-type body region PB is formed in the semiconductor substrate SUB so as to reach a predetermined depth from the upper surface TS of the semiconductor substrate SUB. An n-type source region NS is formed in the body region PB. An impurity concentration in the source region NS is higher than the impurity concentration in the drift region NV. A portion of the body region PB is located below the gate electrode GE via the gate insulating film GI. The portion of the body region PB located below the gate electrode GE via the gate insulating film GI and between the source region NS and the drift region NV in plan view forms a channel region of the MOSFETs 1Q.

An interlayer insulating film IL is formed on the upper surface TS of the semiconductor substrate SUB so as to cover the MOSFETs 1Q. The interlayer insulating film IL has an insulating film IF1, an insulating film IF2 formed on the insulating film IF1, and an insulating film IF3 formed on the insulating film IF2. A thickness of each of the insulating films IF2 and IF3 is larger than a thickness of the insulating film IF1.

The insulating film IF1 is, for example, a TEOS (Tetra Ethoxy Silane) film. The insulating film IF2 is, for example, a silicon oxide film containing boron and phosphorus, and is a BSPG (Boron Phosphorus Silicate Glass) film. The insulating film IF3 is, for example, a silicon oxide film containing phosphorus, and is a PSG (Phosphorous Silicate Glass) film. A gettering layer 10 containing phosphorus is formed in the insulating film IF3.

A hole CH is formed in the interlayer insulating film IL so as to reach the source region NS. In addition, a p-type high-concentration diffusion region PR is formed in the body region PB below the hole CH. An impurity concentration in the high-concentration diffusion region PR is higher than an impurity concentration in the body region PB.

The source electrode SE is formed on the interlayer insulating film IL. The source electrode SE is also formed in the hole CH, is electrically connected to the source region NS, the high-concentration diffusion region PR and the body region PB, and supplies a source potential to these impurity regions.

Although not shown here, in the outer peripheral region OR, the hole CH is formed in the interlayer insulating film IL so as to reach the gate electrode GE. The gate wiring GW is formed on the interlayer insulating film IL and in the hole CH. The gate wiring GW is electrically connected to the gate electrode GE and supplies a gate potential to the gate electrode GE.

### Structure of Outer Peripheral Region

As shown in FIGS. 2 and 3, a plurality of field insulating films IF0 is formed on the upper surface TS of the semiconductor substrate SUB. The field insulating films IF0 are, for example, TEOS films and have thicknesses greater than the gate insulating film GI. The interlayer insulating film IL is formed on the upper surface TS of the semiconductor substrate SUB so as to cover the field insulating films IF0. The gate wiring GW, the source wiring SW, the plurality of field plate wirings FP, and the guard ring wiring GR are formed on the interlayer insulating film IL.

Note that the source electrode SE, the gate wiring GW, the source wiring SW, the plurality of field plate wirings FP, and the guard ring wiring GR are made of, for example, a barrier metal film and a conductive film formed on the barrier metal film. The barrier metal film is, for example, a titanium-tungsten film. The conductive film is, for example, an aluminum alloy film containing copper or silicon.

As shown in FIG. 2, a p-type well region PW1, a p-type well region PW2, a plurality of p-type impurity regions (field-limiting rings) PF, and an n-type impurity region NGR are formed in the semiconductor substrate SUB. An impurity concentration in the impurity region NGR is higher than the impurity concentration of the drift region NV.

A plurality of the holes CH is formed in the interlayer insulating film IL so as to reach the well region PW1, the well region PW2, the plurality of impurity regions PF, and the impurity region NGR. The source electrode SE is formed in the hole CH, is electrically connected to the well region PW1, and supplies a source potential to the well region PW1. The source wiring SW is formed in the hole CH, is electrically connected to the well region PW2, and supplies a source potential to the well region PW2.

The guard ring wiring GR is also formed in the hole CH and is electrically connected to the impurity region NGR. The guard ring wiring GR and the impurity region NGR are electrically connected to the drain electrode DE via the drift region NV and the drain region ND. Therefore, the drain electrode DE supplies a drain potential to the guard ring wiring GR and the impurity region NGR.

The plurality of field plate wirings FP is formed in the plurality of holes CH and is electrically connected to the plurality of impurity regions PF. The plurality of field plate wirings FP and the plurality of impurity regions PF are each electrically floating with respect to each other. Note that, although the first embodiment shows an example where two impurity regions PF are provided, the number of impurity regions PF can be changed as necessary and may be three or more.

The well region PW2, the plurality of impurity regions PF, and the impurity region NGR are respectively formed along the source wiring SW, the plurality of field plate wirings FP, and the guard ring wiring GR as shown in FIG. 1. That is, the well region PW2, the plurality of impurity regions PF, and the impurity region NGR are each formed in the outer peripheral region OR so as to surround the cell region CR in plan view.

As shown in FIG. 3, the interlayer insulating film IL in the outer peripheral region OR has the insulating film IF1, the insulating film IF2, and the insulating film IF3 as in the interlayer insulating film IL in the cell region CR, and the gettering layer 10 containing phosphorus is formed in the insulating film IF3.

### Findings Obtained by the Inventors of the Invention

In the breakdown test, a high voltage of, for example, 1000 V or higher is applied to the guard ring wiring GR electrically connected to the drain electrode DE, while 0 V is applied to the source wiring SW and the gate wiring GW.

The inventors of the present invention found that, in the breakdown test, positive mobile ions cause the breakdown voltage to significantly vary. Note that these mobile ions are hydrogen ions (H+), that is, protons. As sources of the mobile ions, ions introduced during probe testing after completion of the front-end process or an encapsulating resin for encapsulating the semiconductor device 100 in the back-end process are presumed.

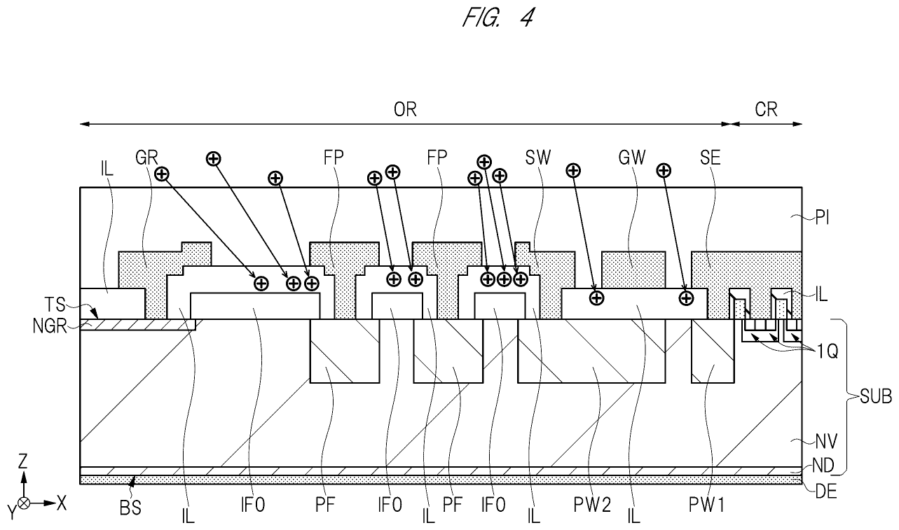

As shown in FIG. 4, positive mobile ions move from the guard ring wiring GR toward the source wiring SW and are trapped in the interlayer insulating film IL. For example, when positive mobile ions are trapped in the interlayer insulating film IL located below the plurality of field plate wirings FP, an extension of the depletion layer extending from the plurality of impurity regions PF becomes smaller, making the semiconductor device 100 more susceptible to a decrease in breakdown voltage. That is, positive mobile ions cause the breakdown voltage of the semiconductor device 100 to significantly vary in the outer peripheral region, leading to a decrease in reliability of the semiconductor device 100.

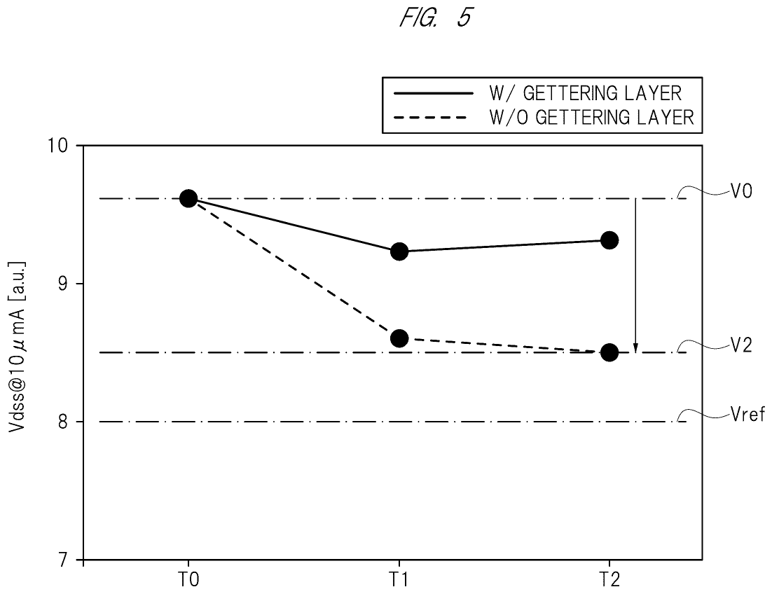

The graph in FIG. 5 shows a relationship between the breakdown voltage Vdss of the semiconductor device 100 and elapsed time of the breakdown test. Time T0 indicates the start of the breakdown test. Time T1 indicates the first measurement. Time T2 indicates the second measurement.

As shown in the “WITHOUT GETTERING LAYER” section of FIG. 5, comparing an initial breakdown voltage V0 at time T0 with the breakdown voltage V2 at time T2, it can be seen that the breakdown voltage Vdss of the semiconductor device 100 decreases over time.

As requirements for passing the breakdown test, it is necessary that, after the breakdown test, the breakdown voltage V2 exceeds a reference breakdown voltage Vref, and that a variation rate of the breakdown voltage Vdss is below a certain value. Note that the variation rate can be calculated using the formula “(initial breakdown voltage V0 breakdown voltage V2)/initial breakdown voltage V0”. As shown in the “WITHOUT GETTERING LAYER” section of FIG. 5, even if the breakdown voltage V2 exceeds the reference breakdown voltage Vref, if the variation rate of the breakdown voltage Vdss exceeds a certain value, the breakdown voltage variation of the semiconductor device 100 is considered to be greater than the reference value.

In order to reduce the variation rate of the breakdown voltage Vdss, it is possible to lower a setting value of the initial breakdown voltage V0. In such a case, a drain voltage applied to the guard ring wiring GR is reduced, making it possible to mitigate the electric field and reduce the amount of trapped positive mobile ions. However, since the setting value of the initial breakdown voltage V0 is lowered, while the semiconductor device 100 can be applied to products requiring a certain level of breakdown voltage, it cannot be applied to products requiring higher breakdown voltage.

In addition, in order to reduce the variation rate of the breakdown voltage Vdss without lowering the setting value of the initial breakdown voltage V0, it is also possible to increase the number of field plate wirings FP and impurity regions PF, and adjust the spacing between them.

However, in a case where the semiconductor device 100 is applied to products requiring higher breakdown voltage, the area where the plurality of field plate wirings FP and the plurality of impurity regions PF are formed must be increased as the breakdown voltage increases. Therefore, it becomes difficult to promote miniaturization of the semiconductor device 100.

In addition, in order to reduce the variation rate of the breakdown voltage Vdss without lowering the setting value of the initial breakdown voltage V0, it is also possible to increase thickness of the protective film PI. However, in a case where the protective film PI is a polyimide film, while polyimide films have high mechanical and thermal strength, they also have a property that easily allows passage of positive mobile ions. Therefore, even if the thickness of the polyimide film is increased, it may not be possible to suppress the passage of positive mobile ions.

In addition, instead of increasing the thickness of the polyimide film, it is also possible to apply an insulating film that is presumed to block transmission of positive mobile ions. The above-described insulating film is formed between the polyimide film and each wiring as a portion of the protective film PI. Candidates for the insulating film include, for example, a silicon nitride film or an acid-treated silicon nitride film formed by film deposition using a plasma CVD (Chemical Vapor Deposition) method.

However, applying the above-described insulating film may result in the protective film PI to become excessively thick, making it difficult to connect external connection members such as wires or clips to the source pad SP and the gate pad GP. That is, when the thickness of the protective film PI is limited, the above-described insulating film cannot be applied.

### Main Features of First Embodiment

As shown in FIG. 3, in the first embodiment, the gettering layer 10 containing phosphorus is formed in the insulating film IF3. The gettering layer 10 has a function of capturing positive mobile ions (hydrogen ions or protons). Specifically, the gettering layer 10 includes a large amount of POHCs (Phosphorus-Oxygen-Hole-Centers) formed by a crystal lattice of phosphorus and oxygen in the silicon oxide film. Positive mobile ions are captured by the POHC.

As concentration of phosphorus increases, the number of POHCs also increases. The concentration of phosphorus in the insulating film IF3 is, for example, greater than or equal to 0.9×10²¹/cm³ and less than or equal to 1.2×10²¹/cm³. The concentration of phosphorus in the gettering layer 10 is higher than the concentration of phosphorus in the insulating film IF3. Therefore, the number of POHCs in the gettering layer 10 is greater than the number of POHCs in the insulating film IF3.

In the first embodiment, such a gettering layer 10 is applied to the interlayer insulating film IL in the outer peripheral region OR. In particular, the gettering layer 10 is applied to the interlayer insulating film IL located below the plurality of field plate wirings FP, making it possible to resolve the problem of the extension of depletion layers extending from the plurality of impurity regions PF. Therefore, as shown in the “WITH GETTERING LAYER” section of FIG. 5, the variation rate of the breakdown voltage Vdss during the breakdown test can be reduced without lowering the setting value of the initial breakdown voltage V0. As a result, the breakdown voltage variation of the semiconductor device 100 in the outer peripheral region OR can be reduced, thereby improving reliability of the semiconductor device 100.

In addition, in a case where the insulating film IF3 is made of a PSG film, forming the gettering layer 10 on the upper surface of the PSG film increases the concentration of phosphorus on the upper surface of the PSG film. As a result, when moisture enters the semiconductor device 100 from the outside, it tends to accumulate on the upper surface of the PSG film. Such moisture may become a factor in reducing reliability of the semiconductor device 100. For example, there is a risk that moisture accumulated on the upper surface of the PSG film may form a leakage path between each of the wirings. In addition, there is a risk that moisture may cause corrosion in each of the wirings formed on the upper surface of the PSG film. Therefore, it is preferable that the gettering layer 10 is formed at a position away from the upper surface of the insulating film IF3.

As will be described below, the gettering layer 10 can be formed by performing ion implantation on the entire interlayer insulating film IL without using a mask. Therefore, the breakdown voltage variation of the semiconductor device 100 can be reduced using a relatively inexpensive method, making it possible to suppress an increase in manufacturing costs. In addition, the breakdown voltage variation of the semiconductor device 100 can be reduced independently of the number of field plate wirings FP and impurity regions PF, making it possible to promote miniaturization of the semiconductor device 100. In addition, there is no need to increase the thickness of the protective film PI, enabling good connection of an external connection member to the source pad SP and the gate pad GP.

In addition, there is a risk that positive mobile ions may be trapped in the gate insulating film GI of the MOSFETs 1Q in the cell region CR, causing a decrease in a threshold voltage of the MOSFETs 1Q. As shown in FIG. 3, in the first embodiment, the interlayer insulating film IL is formed so as to cover the MOSFETs 1Q. In the cell region CR, the gettering layer 10 is formed within the insulating film IF3, and thus, positive mobile ions are captured by the gettering layer 10. Therefore, the risk of the threshold voltage of the MOSFETs 1Q decreasing is resolved.

### Method of Manufacturing Semiconductor Device

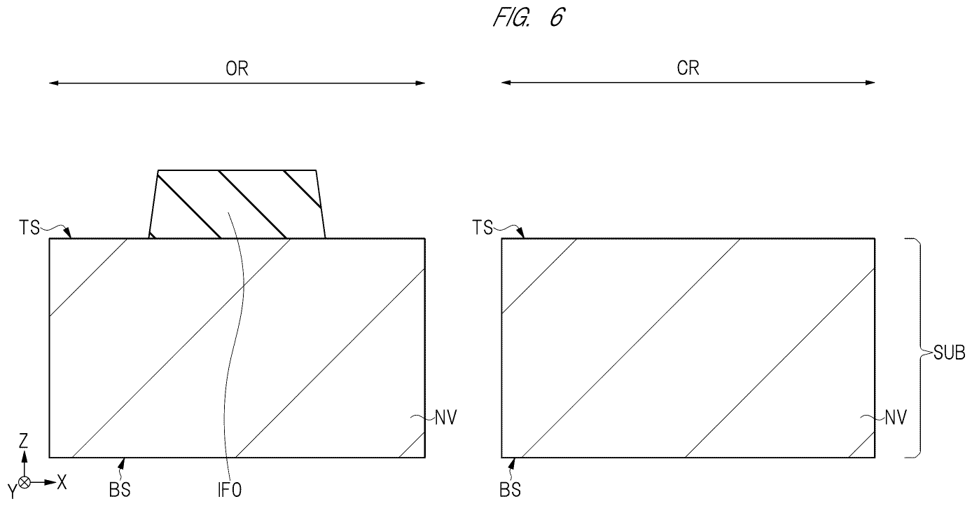

Hereinafter, each manufacturing step in a method of manufacturing the semiconductor device 100 according to the first embodiment will be described with reference to FIGS. 6 to 12.

As shown in FIG. 6, first, the semiconductor substrate SUB having the drift region NV is prepared. As describe above, the semiconductor substrate SUB may be a monocrystalline n-type silicon substrate, or a stack of an n-type silicon substrate and an n-type semiconductor layer formed on the n-type silicon substrate by the epitaxial growth method.

Next, the field insulating film IF0 is formed on the upper surface TS of the semiconductor substrate SUB by, for example, the film deposition process using an atmospheric pressure CVD method. Next, the field insulating film IF0 is patterned to remove the field insulating film IF0 in the cell region CR and leave a portion the field insulating film IF0 in the outer peripheral region OR. As shown in FIG. 2, the plurality of field insulating films IF0 remains in the outer peripheral region OR.

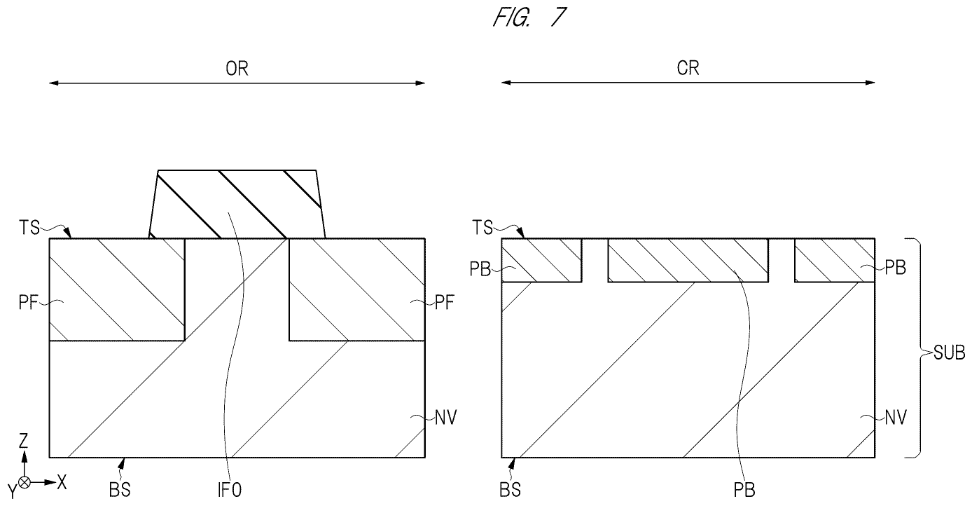

As shown in FIG. 7, first, in the outer peripheral region OR, the plurality of impurity regions PF is selectively formed in the semiconductor substrate SUB by the photolithography technique and ion implantation method. Note that, in this manufacturing step, the well region PW1 and the well region PW2 shown in FIG. 2 are also formed in the semiconductor substrate SUB located in the outer peripheral region OR.

Next, in the cell region CR, a plurality of the body regions PB is selectively formed in the semiconductor substrate SUB by the photolithography technique and ion implantation method.

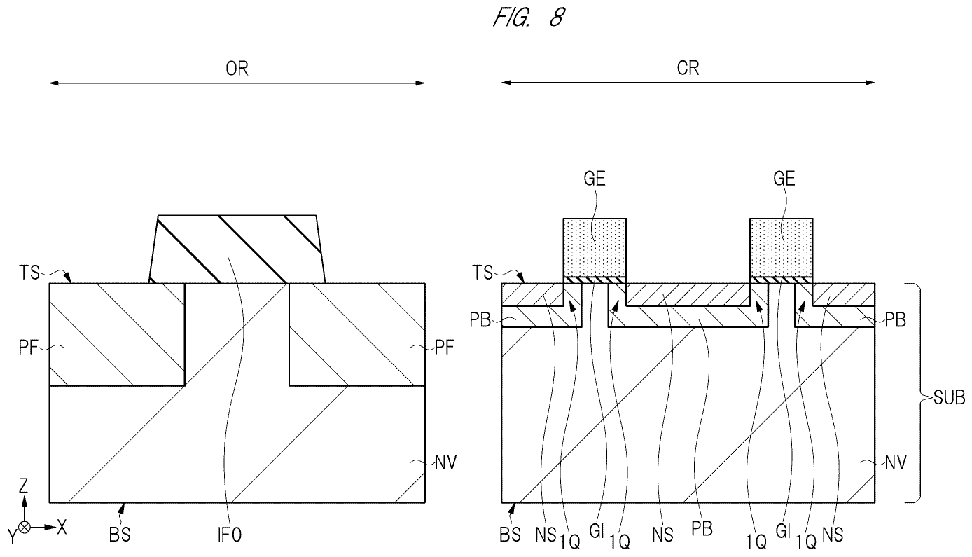

As shown in FIG. 8, a plurality of the MOSFETs 1Q is formed in the cell region CR as the plurality of semiconductor elements.

First, the gate insulating film GI is formed on the upper surface TS of the semiconductor substrate SUB by, for example, a thermal oxidation process. Next, a conductive film is formed on the gate insulating film GI by, for example, the film deposition process using the CVD method. The conductive film is, for example, a polycrystalline silicon film with n-type impurities introduced.

Next, the conductive film is patterned to remove the conductive film located in the outer peripheral region OR, and a plurality of the gate electrodes GE is formed on the gate insulating film GI located in the cell region CR. Next, the gate insulating film GI exposed from the gate electrodes GE is removed by an isotropic etching process. The gate electrodes GE are formed so as to span across a portion of each of the adjacent body regions PB and the drift region NV located between the adjacent body regions PB.

Next, in the cell region CR, using the photolithography technique and ion implantation method, a plurality of the source regions NS is selectively formed in the plurality of body regions PB exposed from the plurality of gate electrodes GE. Note that, in this manufacturing step, the impurity region NGR shown in FIG. 2 is also formed in the semiconductor substrate SUB located in the outer peripheral region OR.

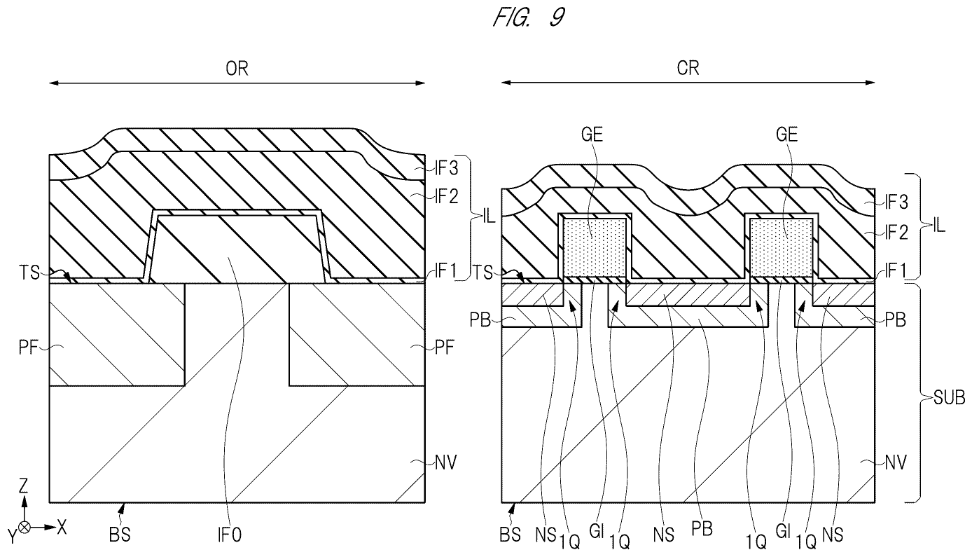

As shown in FIG. 9, the interlayer insulating film IL is formed on the upper surface TS of the semiconductor substrate SUB so as to cover the field insulating film IF0 in the outer peripheral region OR and the MOSFETs 1Q in the cell region CR.

First, the insulating film IF1 is formed on the upper surface TS of the semiconductor substrate SUB by, for example, the film deposition process using the atmospheric pressure CVD method so as to cover the field insulating film IF0 in the outer peripheral region OR and the MOSFETs 1Q in the cell region CR.

Next, the insulating film IF2 is formed on the insulating film IF1 by, for example, the film deposition process using the atmospheric pressure CVD method. Next, a reflow process is performed on the insulating film IF2. In a case where the insulating film IF2 is a BPSG film, the reflow process allows the BPSG film to flow and makes the upper surface of the BPSG film smooth. The plurality of field insulating films IF0 and the plurality of gate electrodes GE cause steps to be formed on the upper surface TS of the semiconductor substrate SUB. Performing the reflow process on the BPSG film reduces these steps.

Next, the insulating film IF3 is formed on the insulating film IF2 by, for example, the film deposition process using the atmospheric pressure CVD method. Next, a reflow process is performed on the insulating film IF3. In a case where the insulating film IF3 is a PSG film, the reflow process allows the PSG film to flow and makes the upper surface of the PSG film smooth. Forming an additional PSG film on the BPSG film to which the reflow process has been performed can further reduce the above-described steps.

Note that, after forming the insulating film IF3, the insulating film IF3 and/or the insulating film IF2 can be polished by a polishing process using a CMP (Chemical Mechanical Polishing) method to flatten the upper surface of the interlayer insulating film IL. However, the reflow process as described above can flatten the upper surface of the interlayer insulating film IL to a certain extent. Therefore, in first embodiment, by the polishing process using the CMP method is omitted to suppress an increase in manufacturing costs.

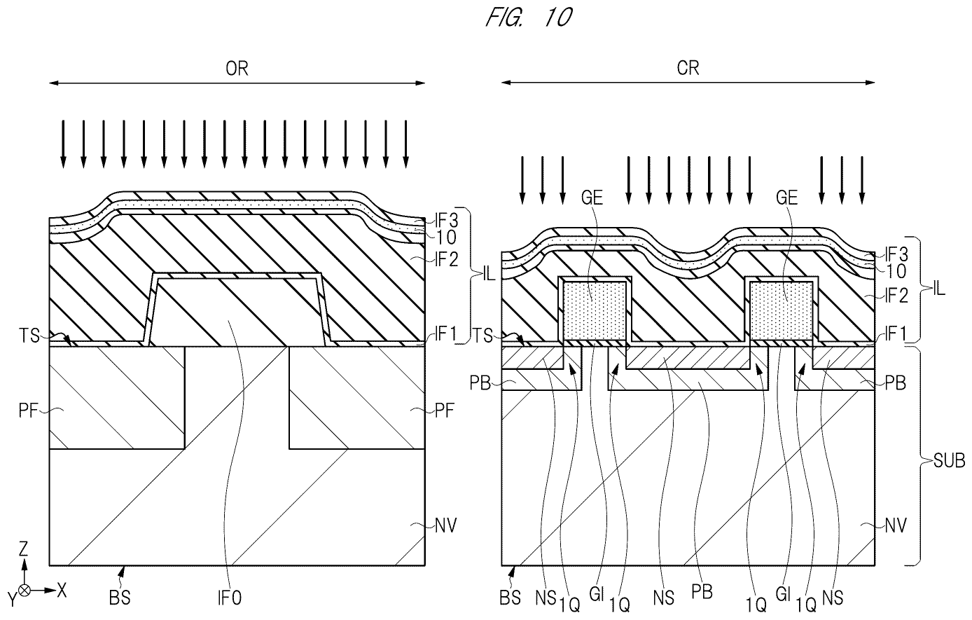

As shown in FIG. 10, phosphorus is injected into the insulating film IF3 with an ion implantation to form the gettering layer 10 in the insulating film IF3. A dose of the ion implantation is, for example, greater than or equal to 1.0×10¹⁶/cm² and less than or equal to 5.0×10¹⁶/cm². By adjusting energy of the ion implantation, the gettering layer 10 is formed at a position away from the upper surface of the insulating film IF3. Note that this ion implantation is performed without using a mask such as a resist pattern.

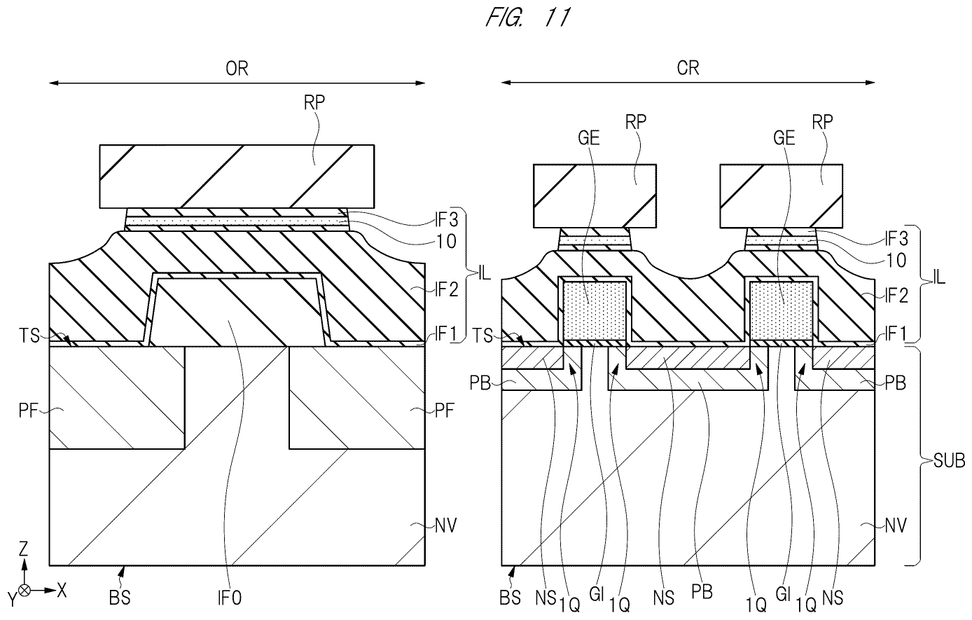

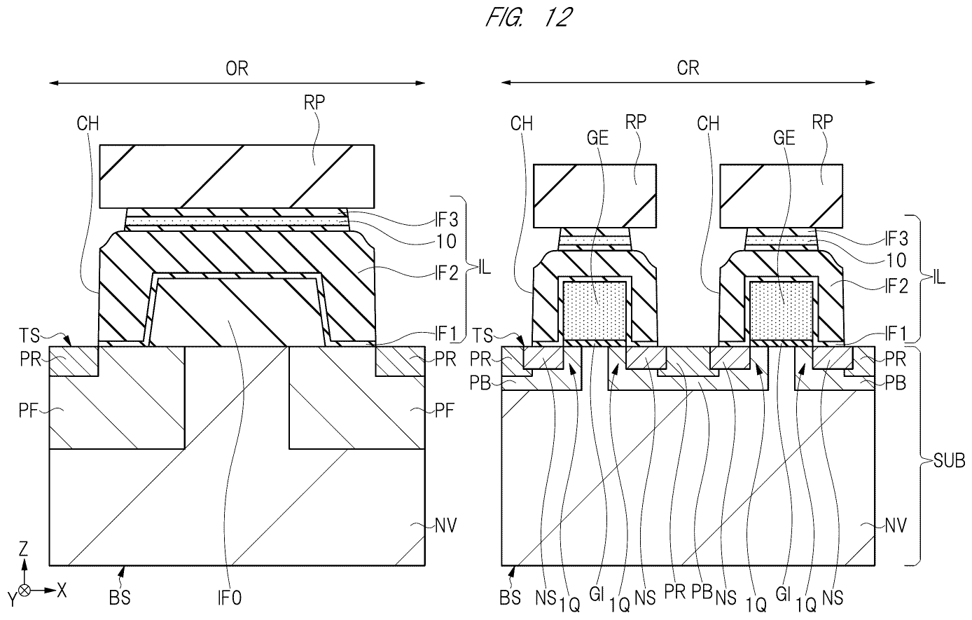

As shown in FIGS. 11 and 12, the plurality of holes CH is formed in the interlayer insulating film IL.

First, as shown in FIG. 11, a resist pattern RP is formed on the interlayer insulating film IL. Next, isotropic etching process is performed using the resist pattern RP as a mask to remove a portion of the interlayer insulating film IL. At this time, etching also proceeds in the X direction, and thus, a portion of the interlayer insulating film IL covered by the resist pattern RP is also removed.

Next, as shown in FIG. 12, isotropic etching process is performed using the resist pattern RP as a mask to form the plurality of holes CH in the interlayer insulating film IL so as to reach the semiconductor substrate SUB. The plurality of holes CH is formed in the cell region CR so as to reach the plurality of source regions NS. The plurality of holes CH is formed in the outer peripheral region OR so as to reach the plurality of impurity regions PF. In addition, the plurality of holes CH is formed in the outer peripheral region OR so as to reach the well region PW1, the well region PW2, and the impurity region NGR shown in FIG. 2.

Note that performing the isotropic etching before anisotropic etching process allows each of the holes CH to have an upper opening width wider than a lower opening width. This makes it easier to embed the wirings into the holes CH during subsequent manufacturing steps.

Next, ion implantation is performed using the resist pattern RP as a mask to form the high-concentration diffusion regions PR in the body region PB, the well region PW1, the well region PW2, and the plurality of impurity regions PF located below the plurality of holes CH. The high-concentration diffusion region PR is primarily formed to enable ohmic contact with the wirings embedded in the holes CH and to prevent latch-up. Note that, in this manufacturing step, the high-concentration diffusion region PR is also formed in the well region PW1 and the well region PW2 located below the plurality of holes CH in the outer peripheral region OR. Next, the resist pattern RP is removed by an ashing process.

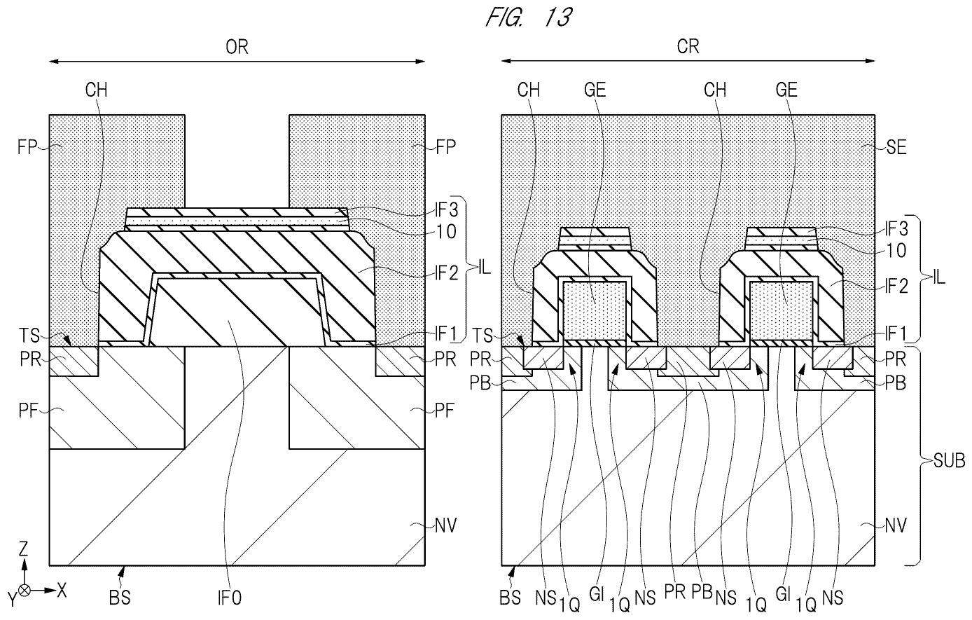

As shown in FIG. 13, the plurality of wirings including the source electrode SE and the plurality of field plate wirings FP are formed on the interlayer insulating film IL and in the plurality of holes CH.

First, the barrier metal film is formed on the interlayer insulating film IL and in the plurality of holes CH by, for example, the film deposition process using a sputtering method. The barrier metal film is, for example, a titanium-tungsten film. Next, a conductive film is formed on the barrier metal film by, for example, the film deposition process using the sputtering method so as to fill the plurality of holes CH. The conductive film is, for example, an aluminum alloy film containing copper or silicon.

Next, the barrier metal film and the conductive film are patterned to form the plurality of wirings. That is, as shown in FIG. 13, the source electrode SE is formed as a wiring in the cell region CR, and the plurality of field plate wirings FP is formed as wirings in the outer peripheral region OR. Note that, in this manufacturing step, the gate wiring GW, the source wiring SW, and the guard ring wiring GR shown in FIG. 2 are also formed as wirings in the outer peripheral region OR.

Subsequently, the semiconductor device 100 shown in FIGS. 2 and 3 is manufactured through the following manufacturing steps. First, the protective film PI is formed by, for example, the film deposition process using a coating method so as to cover the source electrode SE, the gate wiring GW, the source wiring SW, the plurality of field plate wirings FP, and the guard ring wiring GR. Next, an opening is formed in a portion of the protective film PI so as to expose portions of the source electrode SE and the gate wiring GW. Next, the lower surface BS of the semiconductor substrate SUB is polished as necessary. Next, ion implantation is performed on the lower surface BS of the semiconductor substrate SUB to form the drain region ND. Next, for example, the drain electrode DE is formed on the lower surface BS of the semiconductor substrate SUB by, for example, the film deposition process using the sputtering method.

### Second Embodiment

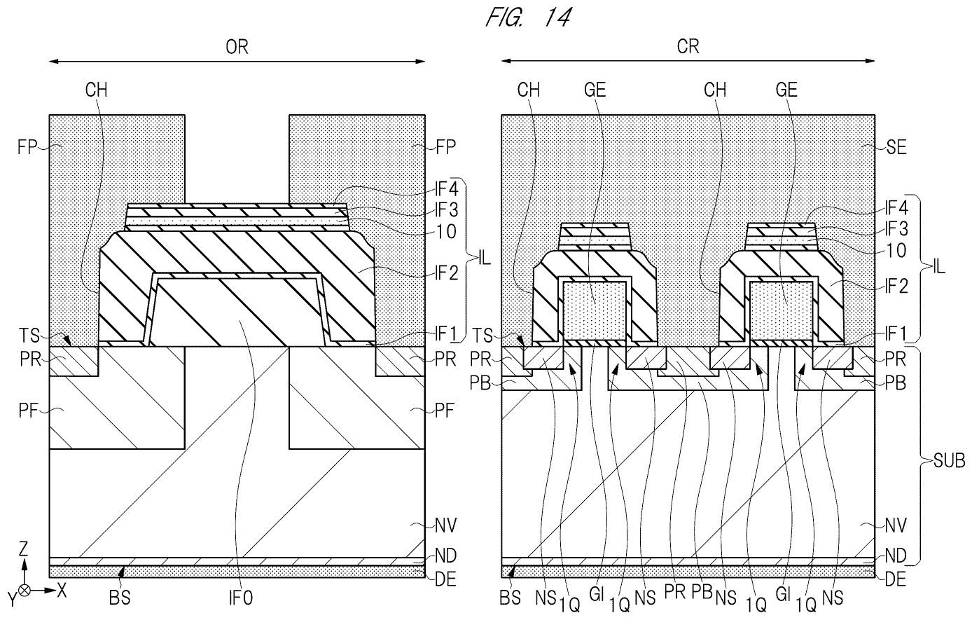

Hereinafter, the semiconductor device according to a second embodiment will be described with reference to FIG. 14. Note that only differences from the first embodiment will be described, and descriptions common to the first embodiment are omitted.

As described for the first embodiment, when the concentration of phosphorus in the upper surface of the insulating film IF3 increases, moisture entering from outside the semiconductor device 100 tends to accumulate on the upper surface of the insulating film IF3. For example, such moisture may become a factor in reducing reliability of the semiconductor device 100. However, in a case where the insulating film IF3 is made of a PSG film, the PSG film itself contains phosphorus. Even if the gettering layer 10 is formed at a position away from the upper surface of the insulating film IF3, compared to a case where the insulating film IF3 is made of, for example, a TEOS film, moisture tends to easily accumulate on the upper surface of the insulating film IF3.

As shown in FIG. 14, in the second embodiment, the interlayer insulating film IL has an additional insulating film IF4 formed on the insulating film IF3. The insulating film IF4 is a phosphorus-free silicon oxide film, and is, for example, an NSG (Non-doped Silicate Glass) film. A thickness of the insulating film IF4 is smaller than the thickness of the insulating film IF3. Compared to the first embodiment, forming the insulating film IF4 in the second embodiment makes it less likely for moisture to accumulate on the upper surface of the interlayer insulating film IL. Therefore, reliability of the semiconductor device 100 can be further improved.

The manufacturing step of forming the insulating film IF4 is performed after the insulating film IF3 is formed and before ion implantation for forming the gettering layer 10 is performed. the insulating film IF4 can be formed on the insulating film IF3 by the film deposition process using the atmospheric pressure CVD method. In addition, during the ion implantation for forming the gettering layer 10, the energy is adjusted to prevent ions from transmitting to the insulating film IF4 and phosphorus from being introduced into the insulating film IF4. Subsequent manufacturing steps are the same as those of the first embodiment.

### Third Embodiment

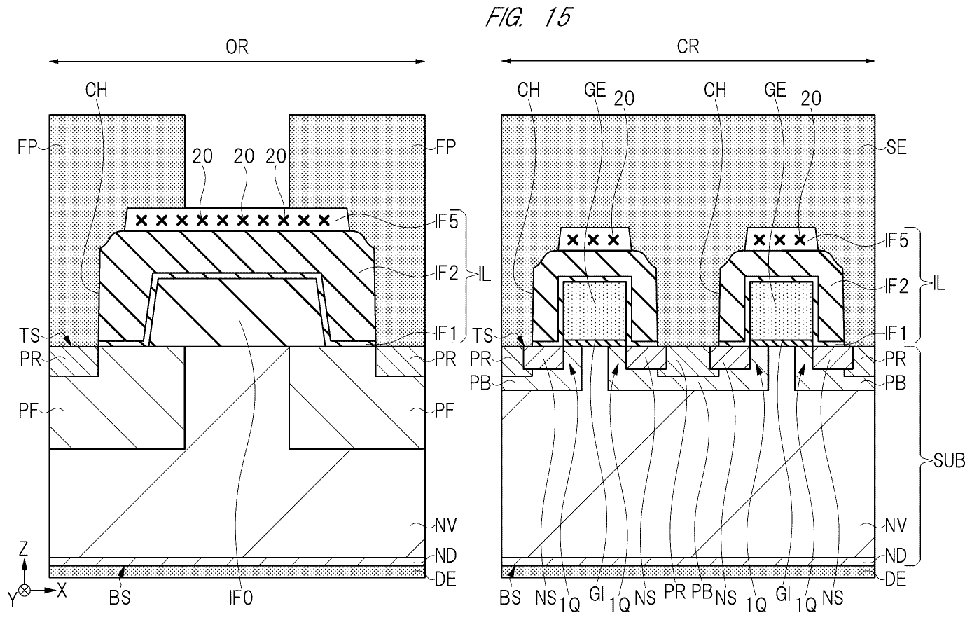

Hereinafter, the semiconductor device according to a third embodiment will be described with reference to FIG. 15. Note that only differences from the first embodiment will be described, and descriptions common to the first embodiment are omitted.

In the first embodiment, the gettering layer 10 is formed in the insulating film IF3, and positive mobile ions are captured by the POHC in the gettering layer 10. In the third embodiment, positive mobile ions are captured by a dangling bond 20 instead of the POHC.

As shown in FIG. 15, in the third embodiment, the interlayer insulating film IL has an insulating film IF5 instead of the insulating film IF3 and the gettering layer 10. The insulating film IF5 is a TEOS film formed by the film deposition process using the plasma CVD method. The insulating film IF5 formed in this manner has a function of capturing positive mobile ions.

The TEOS film formed by the film deposition process using the plasma CVD method includes more dangling bonds 20 than the TEOS film formed by, for example, the film deposition process using the atmospheric pressure CVD method. In addition, the number of dangling bonds 20 in the insulating film IF5 is greater than the number of dangling bonds in the insulating film IF1 or the insulating film IF2. Positive mobile ions are captured by the dangling bonds 20.

The manufacturing step of forming the insulating film IF5 is performed instead of the manufacturing step of forming the insulating film IF3. The insulating film IF5 can be formed on the insulating film IF2 by the film deposition process using the plasma CVD method. In addition, in the third embodiment, ion implantation for forming the gettering layer 10 is not performed. Subsequent manufacturing steps are the same as those of the first embodiment.

In the foregoing, the present invention has been concretely described on the basis of the embodiments. However, the present invention is not limited to the foregoing embodiments, and various modifications can be made within the scope of the present invention.

For example, in the above-described embodiments, the gate insulating film GI and the gate electrode GE of the MOSFETs 1Q are formed on the upper surface TS of the semiconductor substrate SUB, and the MOSFETs 1Q have a planar structure. However, the MOSFETs 1Q may have a trench gate structure. That is, trenches may be formed in the semiconductor substrate SUB so as to reach a predetermined depth from the upper surface TS of the semiconductor substrate SUB, and the gate insulating film GI and the gate electrode GE may be formed in these trenches.

In addition, the semiconductor element formed in the cell region CR is not limited to a MOSFET, and may be an IGBT.

What is claimed is:

1. A semiconductor device comprising:
a semiconductor substrate of a first conductivity type, the semiconductor substrate having an upper surface;
an interlayer insulating film formed on the upper surface of the semiconductor substrate; and
a plurality of wirings formed on the interlayer insulating film,
wherein the interlayer insulating film has:
a BPSG film; and
a PSG film formed on the BPSG film,
wherein a gettering layer containing phosphorus is formed in the PSG film, and
wherein a concentration of phosphorus in the gettering layer is higher than a concentration of phosphorus in the PSG film.

2. The semiconductor device according to claim 1,
wherein the gettering layer has a function of capture hydrogen ions.

3. The semiconductor device according to claim 1,
wherein the gettering layer is formed at a position away from an upper surface of the PSG film.

4. The semiconductor device according to claim 1,
wherein the interlayer insulating film further has a phosphorus-free first silicon oxide film formed on the PSG film, and
wherein a thickness of the first silicon oxide film is smaller than a thickness of the PSG film.

5. The semiconductor device according to claim 4,
wherein the first silicon oxide film is an NSG film.

6. The semiconductor device according to claim 1, further comprising:
a plurality of first impurity regions of a second conductivity type opposite to the first conductivity type formed in the semiconductor substrate; and
a plurality of first holes formed in the interlayer insulating film such that each of the first holes reaches the plurality of first impurity regions,
wherein the plurality of wirings includes a plurality of field plate wirings,
wherein the plurality of field plate wirings is formed in the plurality of first holes so as to be connected to the plurality of first impurity regions, respectively, and
wherein the plurality of field plate wirings and the plurality of first impurity regions are each electrically floating with respect to each other.

7. The semiconductor device according to claim 6, further comprising:
a cell region in which a plurality of semiconductor elements is formed; and
an outer peripheral region surrounding the cell region in plan view,
wherein the plurality of field plate wirings and the plurality of first impurity regions are each formed in the outer peripheral region so as to surround the plurality of semiconductor elements in plan view.

8. The semiconductor device according to claim 6,
wherein the plurality of semiconductor elements has a gate insulating film and a gate electrode, and is covered by the interlayer insulating film.

9. The semiconductor device according to claim 8,
wherein the semiconductor substrate further has a lower surface,
wherein the semiconductor device further has:
a drain electrode formed on the lower surface of the semiconductor substrate;
a drain region of the first conductivity type formed in the semiconductor substrate so as to be in contact with the drain electrode;
a drift region of the first conductivity type formed in the semiconductor substrate and located on the drain region;
a body region of the second conductivity type formed in the semiconductor substrate; and
a source region of the first conductivity type formed in the body region, and
wherein the plurality of semiconductor elements has the gate insulating film, the gate electrode, the drift region, the body region, the source region, and the drain region.

10. A method of manufacturing a semiconductor device, comprising steps of:
(a) preparing a semiconductor substrate of a first conductivity type, the semiconductor substrate having an upper surface;
(b) forming a BPSG film on the upper surface of the semiconductor substrate;
(c) forming a PSG film on the BPSG film;
(d) after the step of (c), forming a gettering layer in the PSG film by injecting phosphorus into the PSG film with an ion implantation; and
(e) after the step of (d), forming a plurality of wirings on the PSG film, and
wherein a concentration of phosphorus in the gettering layer is higher than a concentration of phosphorus in the PSG film.

11. The method according to claim 10,
wherein the gettering layer has a function of capturing hydrogen ions.

12. The method according to claim 10,
wherein the gettering layer is formed at a position away from an upper surface of the PSG film.

13. The method according to claim 10,
wherein, in the step of (d), a dose of the ion implantation is greater than or equal to 1.0×10¹⁶/cm² and less than or equal to 5.0×10¹⁶/cm².

14. The method according to claim 10, further comprising a step of
(f) between the steps of (d) and (e), forming a phosphorus-free first silicon oxide film on the PSG film,
wherein a thickness of the first silicon oxide film is smaller than a thickness of the PSG film, and
wherein, in the step of (e), the plurality of wirings is formed on the first silicon oxide film.

15. The method according to claim 14,
wherein the first silicon oxide film is an NSG film.

16. The method according to claim 10, further comprising steps of:
(g) between the steps of (a) and (b), forming a plurality of first impurity regions of a second conductivity type opposite to the first conductivity type in the semiconductor substrate; and
(h) between the steps of (d)and (e), forming a plurality of first holes in each of the PSG film and the BPSG film such that each of the first holes reach the plurality of first impurity regions,
wherein the plurality of wirings includes a plurality of field plate wirings,
wherein the plurality of field plate wirings is formed in the plurality of first holes so as to be connected to the plurality of first impurity regions, respectively, and
wherein the plurality of field plate wirings and the plurality of first impurity regions are each electrically floating with respect to each other.

17. The method according to claim 16, further comprising a step of
(i) between the steps of (a) and (b), forming a plurality of semiconductor elements,
wherein the semiconductor device comprises a cell region in which the plurality of semiconductor elements is formed, and an outer peripheral region surrounding the cell region in plan view, and
wherein the plurality of field plate wirings and the plurality of first impurity regions are each formed in the outer peripheral region so as to surround the plurality of semiconductor elements in plan view.

18. The method according to claim 17,
wherein the plurality of semiconductor elements has a gate insulating film and a gate electrode, and is covered by the BPSG film and the PSG film.

19. The method according to claim 18,
wherein the semiconductor substrate further has a lower surface, a drain region of the first conductivity type, and a drift region of the first conductivity type located on the drain region,
wherein the step of (i) includes steps of:
(i1) forming a body region of the second conductivity type in the semiconductor substrate;
(i2) forming a source region of the first conductivity type in the body region; and
(i3) forming a drain electrode on the lower surface of the semiconductor substrate, and
wherein the plurality of semiconductor elements has the gate insulating film, the gate electrode, the drift region, the body region, the source region, and the drain region.

20. The method according to claim 10,
wherein the step of (b) includes steps of:
(b1) forming the BPSG film on the upper surface of the semiconductor substrate by a film deposition process using a CVD method; and
(b2) performing a reflow process on the BPSG film, and
wherein the step of (c) includes steps of:
(c1) forming the PSG film on the upper surface of the semiconductor substrate by a film deposition process using the CVD method; and
(c2) performing a reflow process on the PSG film.
